(19) United States
(12) Patent Application Publication
(10) Pub. No.: US 2025/0008644 A1
(43) Pub. Date: Jan. 2, 2025

(54) DISPLAY PANELS AND DISPLAY DEVICES

(71) Applicant: SHENZHEN CHINA STAR OPTOELECTRONICS SEMICONDUCTOR DISPLAY TECHNOLOGY CO., LTD., Shenzhen (CN)

(72) Inventors: Liwang SONG, Shenzhen (CN); Qi WANG, Shenzhen (CN)

(21) Appl. No.: 18/524,171

(22) Filed: Nov. 30, 2023

(30) Foreign Application Priority Data
Jun. 30, 2023 (CN) 202310798577.0

(51) Int. Cl. H05K 1/02

(52) U.S. Cl. CPC H05K 1/0298; H05K 2201/09518; H05K 2201/09609

(57) ABSTRACT

Display panels and display devices are provided. The display panel includes a substrate, a first wiring layer, a second wiring layer, an insulation layer, and a transfer layer. The second wiring layer includes a first connection part and a second connection part respectively disposed at edge portions on both sides of the first wiring layer. Second via holes are provided above the first connection part and the second connection part. First via hole are provided above the first wiring layer. The transfer layer connects the first wiring layer and the second wiring layer through the first via holes and the second via holes.

### CROSS-REFERENCE TO RELATED APPLICATION

This application claims priority to Chinese Patent Application No. 202310798577.0, filed on Jun. 30, 2023, the disclosure of which is incorporated herein by reference in its entirety.

### TECHNICAL FIELD

The present disclosure relates to the field of display technologies, and in particular, to display panels and display devices.

### BACKGROUND

With the development of flexible display technology, people have put forward higher requirements for the quality and performance of display panels and display devices.

In the process of preparing and forming a display panel, in addition to preparing different functional film layers in sequence, it is also necessary to arrange different metal wirings in different film layers to realize the transmission of various signals. When arranging the different metal wirings mentioned above, the metal wirings may be laid directly on an entire surface when they are on the same layer, and a via structure is needed to achieve electrical connection of the metal wirings in upper and lower layers when the metal wirings are on different layers. In related art, when realizing the connection of the metal wirings in the upper and lower layers, via holes are generally directly provided on the two layers of film, and then a transfer layer is provided in the via holes to realize the electrical connection of the metal wirings in the upper and lower layers. However, in the above connection structure, when a distance between the two film layers is large, a depth of the via hole is relatively large, and in the deeper via holes, the transfer layer may easily break, especially in via holes with a large slope, the above-mentioned transfer layer is more likely to break. In the above-mentioned structure, after the transfer is completed, a contact resistance between the upper and lower metal wiring layers is relatively large, which is not conducive to the stability of the signal transmission process and the transfer effect is not ideal, thereby reducing the reliability and overall performance of the display panel.

In summary, when the metal wiring layers in two different layers of the display panel in the related art are transferred, the contact resistance therebetween after transfer is relatively large, the transfer layer is prone to breakage, and the transfer effect is not ideal.

### SUMMARY

In view of above, display panels are provided according to embodiments of the present disclosure. The display panel includes a substrate, a first wiring layer disposed on the substrate, a second wiring layer disposed on and insulated from the first wiring layer, an insulation layer disposed on the second wiring layer, and a transfer layer disposed on the insulation layer. The second wiring layer includes a first connection part and a second connection part electrically connected to the first connection part and disposed on a side of the first connection part. The display panel also includes a plurality of first via holes correspondingly provided above the first wiring layer and a plurality of second via holes correspondingly provided above the first connection part and the second connection part. The transfer layer connects the first wiring layer and the second wiring layer through the first via holes and the second via holes.

Display devices are also provided according to embodiments of the present disclosure. The display device includes the above-mentioned display panel.

### BRIEF DESCRIPTION OF THE DRAWINGS

In order to explain the technical solutions in the embodiments or in the related art more clearly, the drawings needed to be used in the description of the embodiments or the prior art will be briefly introduced below. Obviously, the drawings in the following description are only some embodiments of the present disclosure. For those of ordinary skill in the art, other drawings may be obtained based on these drawings without creative efforts.

FIG. 1 is a schematic structural view of partial film layers of a display panel provided in the related art.

FIG. 2 is a schematic structural view of film layers of a display panel provided according to embodiments of the present disclosure.

FIG. 3 is a schematic plan view of a partial structure of the film layers in FIG. 2.

FIG. 4 is a schematic structural view of film layers corresponding to another arrangement of via holes provided according to embodiments of the present disclosure.

FIG. 5 shows a structure of different via holes in another display panel provided according to embodiments of the present disclosure.

FIG. 6 is a schematic structural view of film layers corresponding to another connection structure provided according to embodiments of the present disclosure.

FIG. 7 are schematic plan views of the structure of FIG. 6 in different directions.

### DETAILED DESCRIPTION

In the following detailed description, certain embodiments of the present disclosure are shown and described by example. As those skilled in the art would realize, the embodiments described herein may be modified in various ways, all without departing from the spirit or scope of the present disclosure.

In the attached drawings, the thickness of layers, films, plates, regions, etc., may be enlarged for clarity and for better understanding and description. It should be understood that when an element such as a layer, film, region, or substrate is referred to as being “on” another element, it may be directly on the other element or other elements may be therebetween.

In addition, unless expressly described to the contrary, the word “include” and variations thereof like “including” or “included” should be understood to imply the inclusion of discussed elements but not necessarily the exclusion of other elements. Further, in the specification, the word “on” refers to being placed above or below the object part, and does not necessarily mean being placed on an upper side of the object part based on the direction of gravity.

It should be understood that, although the terms “first” and “second” etc. may be used herein to describe various components, these components should not be limited by these terms. These components are only used to distinguish one component from another.

As used herein, the singular forms “a”, “an”, and “the” are intended to include the plural forms as well, unless the context clearly indicates otherwise.

In the following examples, the x-axis, y-axis, and z-axis are not limited to the three axes of the cartesian coordinate system and may be interpreted in a broader sense. For example, the x-axis, y-axis, and z-axis may be perpendicular to each other, or may represent different directions that are not perpendicular to each other.

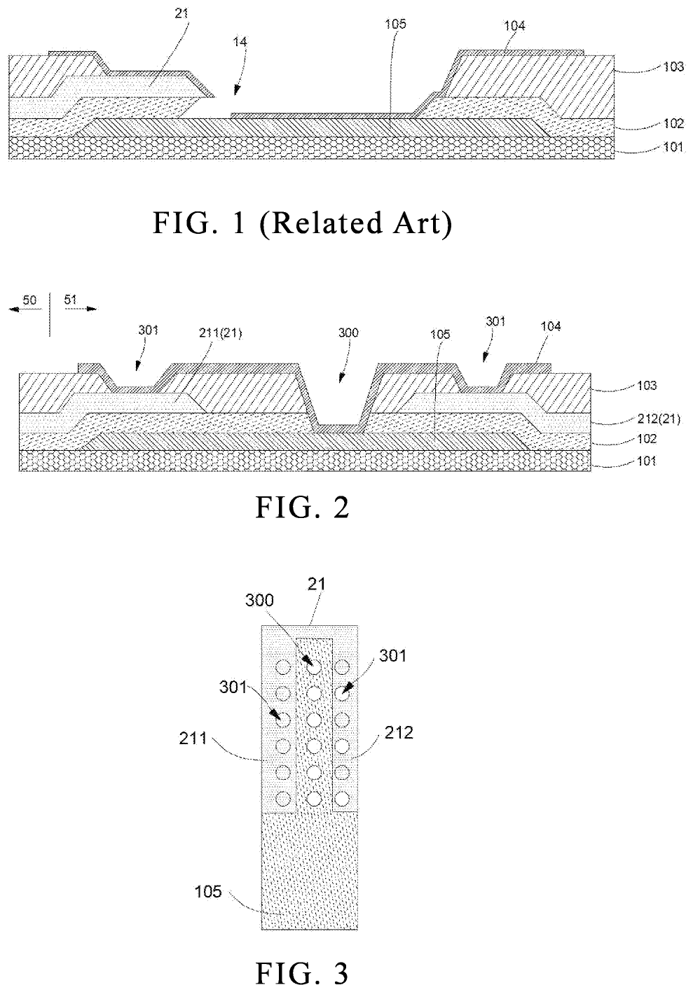

As illustrated in FIG. 1, FIG. 1 a schematic structural view of partial film layers of a display panel provided in the related art. When preparing and forming the above display panel, different film layers are provided on a substrate 101 of the display panel. For example, different metal wiring layers are provided on the substrate 101. Due to performance requirements, metal wirings in different layers are electrically connected, such as a first wiring layer 105 disposed on the substrate 101 and a second wiring layer 21 insulated on the first wiring layer 105. In an existing design, via holes are generally provided directly above the first wiring layer 105, then a transfer layer 104 is provided at the via holes, and the first wiring layer 105 is electrically connected with the second wiring layer 21 through the transfer layer 104, thereby making connections. However, the above-mentioned transfer layer 104 is easily broken at a lateral transition area 14, which may cause the connection between different wiring layers to fail and reduce the quality of the panel.

Embodiments of the present disclosure provide display panels and display devices to effectively improve the problem of unsatisfactory connection effects when connecting wirings in different layers of the display panel.

As illustrated in FIG. 2, FIG. 2 is a schematic structural view of film layers of the display panel provided according to an embodiment of the present disclosure. Specifically, the display panel may include a substrate 101, a first wiring layer 105, a first insulation layer 102, a second wiring layer 21, a second insulation layer 103, and a transfer layer 104.

Specifically, when arranging the film layers of the above-mentioned display panel, the first wiring layer 105 is disposed on the substrate 101, the first insulation layer 102 is disposed on the substrate 101 and covers the first wiring layer 105, the second wiring layer 21 is disposed on the first insulation layer 102, the second insulation layer 103 is disposed on the first insulation layer 102 and covers the second wiring layer 21, and the transfer layer 104 is disposed on the second insulation layer 103.

In the embodiments of the present disclosure, when the above-mentioned film layers are provided, the substrate 101 may also be replaced with a base substrate, such as an array substrate and other structures. By arranging other wirings or film layers on the array substrate, and electrically connecting wirings in different layers, the transmission of control signals is realized.

In the following embodiments, when the second wiring layer 21 is provided, the second wiring layer 21 further includes a first connection part 211 and a second connection part 212. Specifically, the first connection part 211 and the second connection part 212 are both provided on the first wiring layer 105, and the first connection part 211 is provided on a side of the second connection part 212. For example, the first connection part 211 and the second connection part 212 are respectively provided at edges on opposite sides of the first wiring layer 105. In the embodiments of the present disclosure, when the above two different connection parts are provided, they may be formed by directly patterning the second wiring layer 21. For example, a hollow is provided between the first connection part 211 and the second connection part 212 to form the above-mentioned first connecting part and the second connecting part. The first connection part 211 and the second connection part 212 are arranged on the same layer and are electrically connected.

Specifically, the first connection part 211 is provided at an edge on one side of the first wiring layer 105, and the second connection part 212 is provided at an edge on the other side of the first wiring layer 105. At the same time, a projection of the first connection part 211 on the substrate 101 partially overlaps with a projection of the first wiring layer 105 on the substrate 101, and a projection of the second connection part 212 on the substrate 101 partially overlaps with a projection of the first wiring layer 105 on the substrate 101.

Furthermore, in the embodiments of the present disclosure, when the above-mentioned first connection part 211 and second connection part 212 are provided, an overlapping area of projections of the second connection part 212 and the first wiring layer 105 on the substrate is less than an overlapping area of projections of the first connection part 211 and the first wiring layer 105 on the substrate 101. That is, in a direction from a display area 50 towards a non-display area, a length of the second connection part 212 provided above the first wiring layer 105 is shorter than a length of the first connection part 211 provided above the first wiring layer 105. When the film layer is a structure provided in a frame area of the display panel, a width of the frame area is reduced by shortening the length of the second connection part 212.

In the embodiments of the present disclosure, the display panel further includes a plurality of via holes, through which electrical connections between different film layers are achieved. The via holes include a plurality of first via holes 300 disposed correspondingly above the first wiring layer 105 and a plurality of second via holes 301 disposed correspondingly above the first connection part 211 and the second connection part 212 of the second wiring layer 21.

When the above via holes are provided, the first via hole 300 penetrates the first insulation layer 102 and the second insulation layer 103 and exposes part of a surface of the first wiring layer 105. The second via hole 301 above the first connection part 211 penetrates the second insulation layer 103 and exposes part of an upper surface of the first connection part 211. The second via hole 301 above the second connection part 212 penetrates the second insulation layer 103 and exposes part of an upper surface of the second connection part 212.

Correspondingly, the transfer layer 104 is electrically connected to the first wiring layer 105 and the second wiring layer 21 through the first via holes 300 and the second via holes 301. In this way, electrical connections between different film layers are achieved through the transfer layer 104 and the via holes. In the embodiments of the present disclosure, the second wiring layer 21 is designed as two different connection parts when the upper and lower wiring layers are electrically connected, so the two different connection parts may increase a contact area between the transfer layer 104 and the second wiring layer 21 when the different metal layers are connected by the transfer layer 104, which effectively reduces the impedance value between the film layers while ensuring the transfer effect, thereby further enhancing signal stability and eliminating adverse risks between transfer wirings in a vertical structure, which improves product yield and customer satisfaction.

Referring to FIG. 2 for details, in the embodiments of the present disclosure, when the above-mentioned second wiring layer 21 is provided, the structure may be arranged in a non-display area of the display panel. For example, the first wiring layer 105 and the second wiring layer 21 may be film layer structures in a bonding area 51 of the display panel. The first connection part 211 is disposed in the display area 50 and extends into the bonding area 51, and the second connection part 212 is disposed on a side of the bonding area 51 away from the display area 50. The first via holes 300 are provided in the middle of the bonding area 51. At this monment, the first via hole 300 is equivalent to a changeover hole between different film layers. Optionally, the above transfer structure may also be arranged in other areas, which will not be described here.

In the embodiments of the present disclosure, the second wiring layer includes the first connection part and the second connection part that are electrically connected, and the first connection part and the second connection part are respectively provided on edges on opposite sides of the first wiring layer. The first connection part 211 and the second connection part 212 are correspondingly arranged on opposite sides of the first via holes 300, and the second connection part 212 is arranged close to an outer edge of the bonding area. When connected through the transfer layer 104, the transfer layer 104 electrically connects the second wiring layer 21 and the first connection part 211 on a left side of the first via holes 300 through the plurality of second via holes 301 above the first connection part 211, and the transfer layer 104 electrically connects the second wiring layer 21 and the second connection part 212 on a right side of the first via holes 300 through the plurality of second via holes 301 above the second connection part 212. In this way, the contact area between the transfer layer 104 and the second wiring layer 21 may be further increased, thereby effectively reducing the impedance between the wirings and improving the stability of the transmission signal.

Furthermore, when arranging the plurality of second via holes above the second wiring layer 21, it can be referred to FIG. 3, which is a schematic plan view of a partial structure of the film layers in FIG. 2. In the embodiments of the present disclosure, when arranging the via holes in different areas above the first wiring layer 105 and the second wiring layer 21, the plurality of first via holes 300 may be arranged side by side, such as being arranged side by side in a column (that is, arranged side by side in a direction perpendicular to the direction from the display area 50 towards the non-display area) in multiple columns. The second via holes 301 may also be arranged side by side above the first connection part 211 and above the second connection part 212. In the following embodiments, the via holes in each different area are taken as one column. Optionally, they may also be arranged in multiple columns according to different structures. When arranged in multiple columns, an arrangement mode may be referred to the structure of one column of via holes.

Column directions of the via holes corresponding to the first connection part 211, the second connection part 212, and the first wiring layer 105 may be parallel to each other, that is, the columns of via holes are arranged in a same direction, which is perpendicular to the direction from the display area 50 towards the non-display area. At the same time, in each column, a distance between two adjacent via holes is the same. referring to FIG. 3 for details, three rows of via holes are provided side by side in different areas. In the embodiments of the present disclosure, a diameter of the first via hole 300 may be greater than a diameter of the second via hole 301. At the same time, each of the second via holes 301 above the first connection part 211 and a corresponding one of the plurality of second via holes 301 above the second connection part 212 may be arranged symmetrically with respect to a center of a corresponding one of the first via holes 300, thereby ensuring a contact area between the transfer layer 104 and the first wiring layer 105, improving their contact performance, and ensuring that the structures in different areas have a certain symmetry to reduce the impact of structural differences on performance.

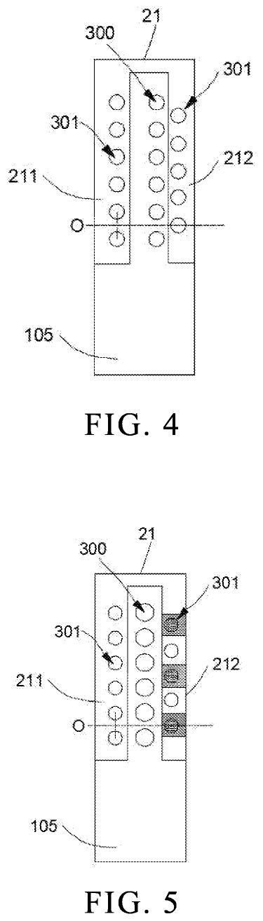

As illustrated in FIG. 4, FIG. 4 is a schematic structural view of the film layers corresponding to another arrangement of the via holes provided according to embodiments of the present disclosure. Combined with the arrangement of the via holes illustrated in FIG. 3, in the embodiments of the present disclosure, since the second connection part 212 is provided at the edge of the bonding area, a distance between each of the second via holes 301 arranged side by side above the second connection part 212 and the corresponding first via hole 300 is less than a distance between the second via hole 301 above the first connection part 211 and the corresponding first via hole 300. In this way, the width of the second connection part 212 may be reduced to marrow the frame of the panel.

Furthermore, when the second via holes 301 above the second connection part 212 are provided, a density or number of the second via holes 301 above the second connection part 212 is less than or equal to a density or number of the second via holes 301 above the first connection part 212. In this way, more second via holes 301 are provided above an inner part of the second wiring layer to improve the connection effect between the transfer layer 104 and the first connection part 211. At the same time, the transfer layer 104 is also connected to the second connection part 212, i.e. an outer part of the second wiring layer, to effectively reduce the impedance between different metal layers and improve the stability during signal transmission. Furthermore, since the transfer layer 104 is also electrically connected to the second connection part 212 on the right side, when the connection between the transfer layer 104 and the first connection part 211 fails, the connection structure on the second connection part 212 may ensure that the panel can still work properly, which improves panel reliability.

Furthermore, in the embodiments of the present disclosure, when different second via holes 301 are provided above the first connection part and the second connection part, each of the second via holes 301 above the second connection part 212 may be correspondingly provided at a position between two second via holes 301 above the first connection part 211. For example, there is a perpendicular bisector O between two adjacent second via holes 301 above the first connection part 211, and the corresponding second via hole 301 above the second connection part 212 is arranged on the perpendicular bisector O. In this way, the second via holes on different connection parts form a staggered structure. By being arranged in the staggered structure, when connected through the transfer layer 104, the transfer layer 104 may contact the film layers in different areas, which makes the connection between different metal layers more stable to ensure the performance of the panel.

As illustrated in FIG. 5, FIG. 5 shows a structure of different via holes in another display panel provided according to embodiments of the present disclosure. Combined with the structure in FIG. 3 and FIG. 4, in the embodiments of the present disclosure, when different via holes are formed, for example, when side-by-side second via holes 301 are respectively formed above the first connection part 211 and the second connection part 212, for example, 2N second via holes are provided above the second connection part 212, serial numbers of the second via holes are marked as 1, 2, 3, 4, 5 . . . 2N starting from one side.

When the second connection part 212 is connected to the transfer layer through the second via holes, the transfer layer 104 is only electrically connected to portions of the second wiring layer corresponding to the second via holes 301 with even numbers. In this way, the transfer layer 104 is connected to different second via holes above the second connection part 212 in a misaligned and crossed way. Thus, while ensuring the improvement of transfer effect, the impedance between different metal layers is effectively reduced, and the reliability and comprehensive performance of the panel is improved.

Furthermore, in the embodiments of the present disclosure, when the second connection part 212 is provided and the different connection parts are deposited, a thickness of the second connection part 212 may be greater than a thickness of the first connection part 211. In this way, by increasing the thickness of the second connection part 212 and combining with the second via holes 301 above it, after the transfer layer 104 connecting the first wiring layer and the second wiring layer, the contact resistance between the first wiring layer and the second wiring layer may be further reduced, which improves the quality and reliability of the second wiring layer.

In the embodiments of the present disclosure, when arranging the first via holes and the second via holes, patterned structures may also be provided on portions of the first wiring layer 105 and the second wiring layer 21 exposed in the via holes, such as a convex and concave microstructure is provided on a surface of the first wiring layer 105. When the exposed surface of the first wiring layer 105 is provided with a concave structure, and when the exposed surface is electrically connected to the transfer layer 104, a corresponding protruding structure is provided on the top of the transfer layer 104, and the protruding structure and the concave structure match each other. Similarly, when arranging the second wiring layer, the surface structure of the first wiring layer may be referred to, which will not be described again here. In this way, the contact area and connection effect between different metal layers are increased, and the performance of the panel is ensured.

Furthermore, in the embodiments of the present disclosure, combined with the film layer structure illustrated in FIG. 2, in the embodiments of the present disclosure, when arranging the second via holes 301 above the first connection part 211, each of the second via holes 301 in this area has a slope of a side wall less than a slope of a side wall of the second via hole above the second connection part 212. In this way, a problem that the transfer layer 104 may break at the side wall of the via hole when it is connected to the first connection part 211 may be relieved, thereby improving the quality of the panel.

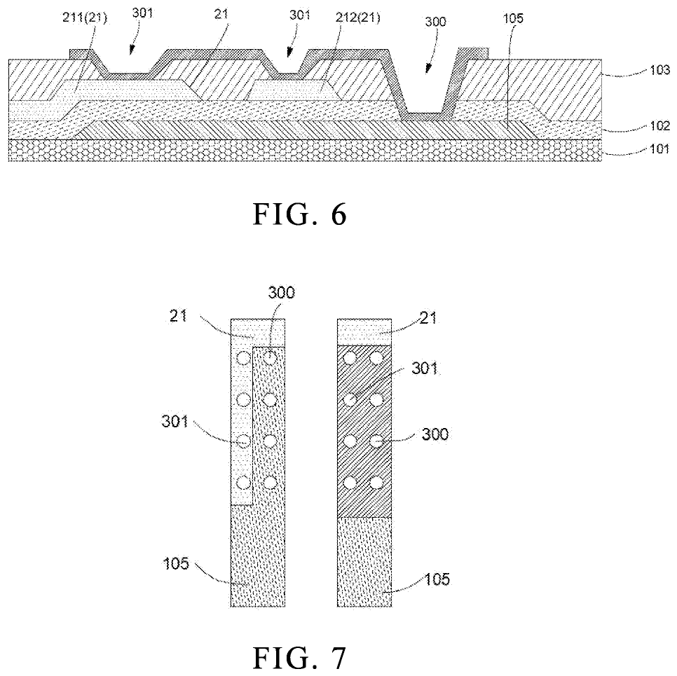

As illustrated in FIG. 6 and FIG. 7, FIG. 6 is a schematic structural view of film layers corresponding to another connection structure provided according to embodiments of the present disclosure, and FIG. 7 are schematic plan views of the structure of FIG. 6 in different directions. Combined with the structure in FIG. 2, in the embodiments of the present disclosure, when the upper and lower wiring layers are electrically connected, the first connection part 211 and the second connection part 212 of the second wiring layer 21 may also be provided on the same side of the first via holes 300. When connecting, a plurality of second via holes 301 are respectively provided above the first connection part 211 and the second connection part 212. When the transfer layer 104 electrically connects two different wiring layers, the connection mode, as well as the structures of the second via holes 301 above different connection parts, and the structures of the first via holes 300 may be arranged by referring to the structures when the two connection parts are arranged on opposite sides of the first via holes. This effectively reduces the contact resistance and improves the performance of the panel while ensuring the connection effect.

Furthermore, in the embodiments of the present disclosure, display devices are also provided. The display device includes the display panel provided in the embodiments of the present disclosure. When different film layers in the display panel are transferred, by arranging different via holes, and electrically connecting the transfer layer to exposed wirings of the via holes in the corresponding area, the transfer effect is effectively improved and the contact resistance is reduced, which effectively improves the reliability and comprehensive performance of the display panel.

In summary, the display panels and display devices provided in the embodiments of the present disclosure have been introduced in detail. This paper uses specific examples to illustrate the principles and implementation methods of the present disclosure. The description of the above embodiments is only for reference to help understand the technical solutions and core ideas of the present disclosure. Although the present disclosure is disclosed as above in preferred embodiments, the above preferred embodiments are not intended to limit the present disclosure. Those of ordinary skill in the art may make various modifications and modifications without departing from the spirit and scope of the present disclosure. Therefore, the protection scope of the present disclosure is based on the scope defined by the claims.

What is claimed is:

1. A display panel, comprising:
a substrate;
a first wiring layer, disposed on the substrate;
a second wiring layer, disposed on and insulated from the first wiring layer, and comprising:
a first connection part; and
a second connection part, electrically connected to the first connection part, and disposed on a side of the first connection part;
an insulation layer, disposed on the second wiring layer, and provided with a plurality of first via holes above the first wiring layer and a plurality of second via holes above the first connection part and the second connection part; and
a transfer layer, disposed on the insulation layer, and connecting to the first wiring layer and the second wiring layer through the plurality of first via holes and the plurality of second via holes.

2. The display panel according to claim 1, wherein a distance between each of the second via holes above the first connection part and a corresponding one of the first via holes is greater than or equal to a distance between each of the second via holes above the second connection part and a corresponding one of the first via holes.

3. The display panel according to claim 2, wherein each of the second via holes above the second connection part is arranged on a perpendicular bisector between two adjacent ones of the second via holes above the first connection part.

4. The display panel according to claim 2, wherein each of the second via holes above the first connection part and a corresponding one of the second via holes above the second connection part are arranged symmetrically with respect to a center of a corresponding one of the first via holes.

5. The display panel according to claim 4, wherein the plurality of first via holes are arranged side by side and at equal intervals, the second via holes above the first connection part are arranged side by side and at equal intervals, and the second via holes above the second connection part are arranged side by side and at equal intervals.

6. The display panel according to claim 5, wherein an arrangement direction of the plurality of first via holes, an arrangement direction of the second via holes above the first connection part, and an arrangement direction of the second via holes above the second connection part are the same.

7. The display panel according to claim 1, wherein a number of the second via holes above the first connection part is greater than or equal to a number of the second via holes above the second connection part.

8. The display panel according to claim 1, wherein a diameter of each of the second via holes above the first connection part is less than or equal to a diameter of each of the second via holes above the second connection part, and the diameter of each of the second via holes is less than a diameter of each of the first via holes.

9. The display panel according to claim 1, wherein a projection of the first connection part on the substrate partially overlaps with a projection of the first wiring layer on the substrate, and a projection of the second connection part on the substrate partially overlaps with the projection of the first wiring layer on the substrate;
the second via holes above the first connection part are all arranged in an overlapping area of the first connection part and the first wiring layer, the second via holes above the second connection part are all arranged in an overlapping area of the second connection part and the first wiring layer, and each of the second via holes exposes part of the second wiring layer.

10. The display panel according to claim 9, wherein the display panel further comprises a display area and a non-display area, the first connection part is disposed in the display area and extends into the non-display area, the second connection part is disposed in at an edge on a side of the non-display area away from the display area.

11. The display panel according to claim 10, wherein an overlapping area of projections of the second connection part and the first wiring layer on the substrate is less than an overlapping area of projections of the first connection part and the first wiring layer on the substrate.

12. The display panel according to claim 11, wherein in a direction from the display area towards the non-display area, a length of the second connection part is shorter than a length of the first connection part.

13. The display panel according to claim 1, wherein the first connection part and the second connection part are respectively provided on opposite sides of the plurality of first via holes.

14. The display panel according to claim 13, wherein the plurality of first via holes are arranged side by side in one or more columns each having a column direction perpendicular to an arrangement direction of the first connection part and the second connection part.

15. The display panel according to claim 14, wherein the second via holes above the first connection part and the second connection part are arranged side by side in one or more columns each having a column direction parallel to the column direction of the plurality of first via holes.

16. The display panel according to claim 14, wherein the second via holes above the second connection part are arranged side by side in one column, and the transfer layer is only electrically connected to portions of the second wiring layer corresponding to the second via holes above the second connection part with even numbers starting from any end of the column.

17. The display panel according to claim 1, wherein the first connection part and the second connection part are provided on a same side of the plurality of first via holes.

18. The display panel according to claim 1, wherein each of the second via holes above the first connection part has a slope of a side wall less than a slope of a side wall of each of the second via holes above the second connection part.

19. The display panel according to claim 1, further comprising:
another insulation layer, defined as a first insulation layer, disposed on the substrate and covering the first wiring layer,
wherein the second wiring layer is disposed on the first insulation layer, the insulation layer disposed on the second wiring layer is defined as a second insulation layer, the second insulation layer is disposed on the first insulation layer and covering the second wiring layer; and
wherein the transfer layer is disposed on the second insulation layer, each of the first via holes penetrates the first insulation layer and the second insulation layer to expose part of the first wiring layer, and each of the second via holes above the first connection part penetrates the second insulation layer to expose part of the first connection part, and each of the second via holes above the second connection part penetrates the second insulation layer to expose part of the second connection part.

20. A display device, comprising a display panel, and the display panel comprising:
a substrate;
a first wiring layer, disposed on the substrate;
a second wiring layer, disposed on and insulated from the first wiring layer, and comprising:
a first connection part; and
a second connection part, electrically connected to the first connection part, and disposed on a side of the first connection part;
an insulation layer, disposed on the second wiring layer, and provided with a plurality of first via holes above the first wiring layer and a plurality of second via holes above the first connection part and the second connection part; and
a transfer layer, disposed on the insulation layer, and connecting to the first wiring layer and the second wiring layer through the plurality of first via holes and the plurality of second via holes.
